(19) United States
(12) Patent Application Publication
(10) Pub. No.: US 2026/0121650 A1
(43) Pub. Date: Apr. 30, 2026

(54) ELECTRONIC SYSTEM WITH CURRENT-STEERING DIGITAL-TO-ANALOG CONVERTER USING CONVERSION CELLS CAPABLE OF GLITCH ELIMINATION AND SKEW ALIGNMENT

(71) Applicant: MEDIATEK INC., Hsinchu City (TW)

(72) Inventors: Kid Nuo LIM, Hsinchu City (TW); Hung-Yi HUANG, Hsinchu City (TW); Wei-Te LIN, Hsinchu City (TW); Wei-Hsin TSENG, Hsinchu City (TW); Kuan-Ta CHEN, Hsinchu City (TW)

(21) Appl. No.: 19/274,872

(22) Filed: Jul. 21, 2025

Related U.S. Application Data
(60) Provisional application No. 63/714,172, filed on Oct. 31, 2024.

(51) Int. Cl. H03M 1/06

(52) U.S. Cl. CPC H03M 1/0678; H03M 1/0612

(57) ABSTRACT

An electronic system with a current-steering digital-to-analog converter using conversion cells capable of glitch elimination and skew alignment is shown. In a conversion cell, a differential switch pair is controlled by an input signal and an inverted input signal, to couple a current source to a positive output terminal and a negative output terminal of a differential analog output port. A cascode pair is coupled between the differential switch pair and the differential analog output port. A glitch elimination pair is controlled by the input signal and the inverted input signal to eliminate glitches at the differential analog output port. The glitch elimination pair is coupled to the differential analog output port without passing through the cascode pair. At the differential analog output port, the parasitic capacitance due to the glitch elimination pair is relatively small. The glitch elimination performance is thereby improved.

### CROSS REFERENCE TO RELATED APPLICATIONS

This application claims the benefit of U.S. Provisional Application No. 63/714,172, filed Oct. 31, 2024, the entirety of which is incorporated by reference herein.

### BACKGROUND OF THE INVENTION

### Field of the Invention

The present invention relates to an electronic system using a current-steering digital-to-analog converter (DAC).

### Description of the Related Art

Today's electronic systems often require digital-to-analog conversion. One of the most commonly used digital-to-analog converters (DACs) is the current-steering DAC.

A current-steering DAC usually uses metal-oxide-semiconductor field-effect transistors (MOSFETs, or MOSs) as switches to conduct current to an output port based on the digital input. The transition (high-to-low, or low-to-high) of any bit of the digital input may cause glitches at the output port of the current-steering DAC.

In addition to the glitch problem, a current-steering DAC including conversion cells corresponding to the different contribution weights may require skew alignment between the different conversion cells.

A novel electronic system with a novel current-steering DAC using conversion cells capable of glitch elimination or even skew alignment is called for.

### BRIEF SUMMARY OF THE INVENTION

An electronic system including a current-steering digital-to-analog converter (DAC) in accordance with an exemplary embodiment of the disclosure is shown. The current-steering DAC comprises a plurality of conversion cells. Each conversion cell has a differential switch pair, a cascode pair, and a glitch elimination pair. The differential switch pair is controlled by an input signal and an inverted input signal, to couple a current source to a positive output terminal and a negative output terminal of a differential analog output port. The cascode pair is coupled between the differential switch pair and the differential analog output port. The glitch elimination pair is also controlled by the input signal and the inverted input signal, and is configured to eliminate glitches at the differential analog output port. Specifically, the glitch elimination pair is coupled to the differential analog output port without passing through the cascode pair. At the differential analog output port, the parasitic capacitance due to the glitch elimination pair of each conversion cell is relatively small. The glitch elimination performance is considerably improved.

In an exemplary embodiment, the glitch elimination pair comprises a first glitch elimination transistor and a second glitch elimination transistor. A gate terminal of the first glitch elimination transistor is controlled by the input signal. A source terminal and a drain terminal of the first glitch elimination transistor are connected together, and further coupled to the negative output terminal without passing through the cascode pair. A gate terminal of the second glitch elimination transistor is controlled by the inverted input signal. A source terminal and a drain terminal of the second glitch elimination transistor are connected together, and further coupled to the positive output terminal without passing through the cascode pair.

In another exemplary embodiment, the glitch elimination pair comprises a first glitch elimination transistor and a second glitch elimination transistor. A gate terminal of the first glitch elimination transistor is controlled by the input signal. A drain terminal of the first glitch elimination transistor is coupled to the negative output terminal without passing through the cascode pair. A gate terminal of the second glitch elimination transistor is controlled by the inverted input signal. A drain terminal of the second glitch elimination transistor is coupled to the positive output terminal without passing through the cascode pair. A source terminal of the first glitch elimination transistor and a source terminal of the second glitch elimination transistor are connected together. In some exemplary embodiments, the source terminal of the first glitch elimination transistor and the source terminal of the second glitch elimination transistor are controlled by a skew alignment voltage, for skew alignment between the different conversion cells.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates an electronic system 100 including a current-steering digital-to-analog converter (DAC) 102 in accordance with an exemplary embodiment of the disclosure;

FIG. 2 depicts a conversion cell 200 in accordance with an exemplary embodiment of the disclosure;

FIG. 3 depicts a conversion cell 300 capable of glitch elimination as well as skew alignment in accordance with an exemplary embodiment of the disclosure; and

FIG. 4 illustrates a current-steering DAC 400 using dummy transistors in its glitch elimination design.

### DETAILED DESCRIPTION OF THE INVENTION

The following description enumerates various embodiments of the disclosure, but is not intended to be limited thereto. The actual scope of the disclosure should be defined according to the claims. The various blocks may be implemented by special circuits. The circuit components may be directly connected to each other without additional components as the circuit illustrated in the figures. Or, there may be some additional components coupled between the illustrated circuit components.

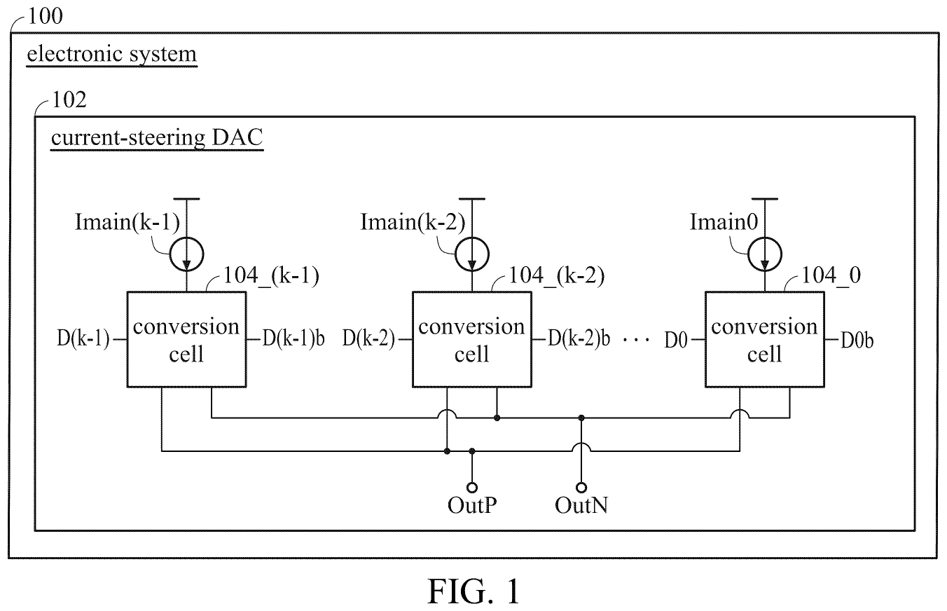

FIG. 1 illustrates an electronic system 100 including a current-steering digital-to-analog converter (DAC) 102 in accordance with an exemplary embodiment of the disclosure. The electronic system 100 may be a circuit, a chip, or an electronic product (e.g., a cell phone, a tablet, and so on). The current-steering DAC 102 is configured to convert a k-bit digital input into a differential analog output. The k-bit digital input is formed by input signals D(k−1), D(k−2), . . . , D0, where D(k−1) is the most significant bit (MSB), and D0 is the least significant bit (LSB). The differential analog output is generated between a positive output terminal OutP and a negative output terminal OutN of a differential analog output port. The current steering DAC 102 includes k conversion cells 104_(k−1), 104_(k−2), . . . 104_0 corresponding to the different contribution weights (from MSB to LSB). Each conversion cell 104_#(where #represents a number) receives an input signal D #and its inverted input signal D #b, to determine how to conduct the corresponding current source Imain #to the positive output terminal OutP and a negative output terminal OutN of a differential analog output port to generate a differential analog output. In this disclosure, each conversion cell 104_#is specially designed to directly eliminate glitches at the positive output terminal OutP and a negative output terminal OutN of the differential analog output port. The proposed glitch elimination components are directly connected to the differential analog output port without passing through the main current path related to the digital-to-analog conversion.

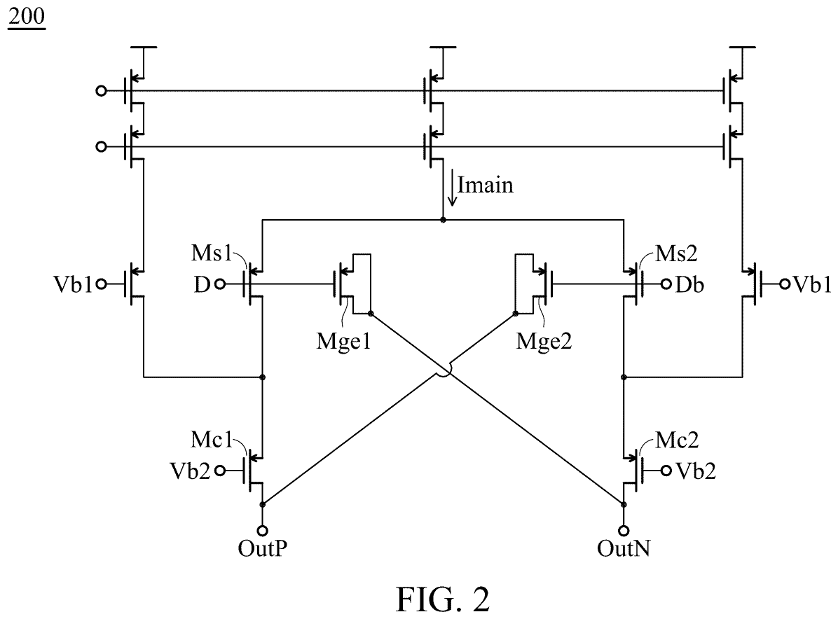

FIG. 2 depicts a conversion cell 200 in accordance with an exemplary embodiment of the disclosure. The conversion cell 200 includes a differential switch pair (including a first switch transistor Ms1 and a second switch transistor Ms2), a cascode pair (including a first cascode transistor Mc1 and a second cascode transistor Mc2), and a glitch elimination pair (including a first glitch elimination transistor Mge1 and a second glitch elimination transistor Mge2). The connection of the glitch elimination pair (Mge1 and Mge2) is specially designed, to directly provide glitch elimination at the positive output terminal OutP and a negative output terminal OutN of a differential analog output port, without passing through the cascode pair (Mc1 and Mc2).

As shown, a source terminal of the first switch transistor Ms1 is coupled to the current source Imain, a drain terminal of the first switch transistor Ms1 is coupled to a source terminal of the first cascode transistor Mc1, and a drain terminal of the first cascode transistor Mc1 is coupled to the positive output terminal OutP. A gate terminal of the first switch transistor Ms1 is controlled by the input signal D to couple the current source Imain to the positive output terminal OutP through the first cascode transistor Mc1. As for the negative path, a source terminal of the second switch transistor Ms2 is coupled to the current source Imain, a drain terminal of the second switch transistor Ms2 is coupled to a source terminal of the second cascode transistor Mc2, and a drain terminal of the second cascode transistor Mc2 is coupled to the negative output terminal OutN. A gate terminal of the second switch transistor Ms2 is controlled by the inverted input signal Db to couple the current source Imain to the negative output terminal OutN through the second cascode transistor Mc2. A current-steering structure for digital-to-analog conversion is shown.

In FIG. 2, a gate terminal of the first glitch elimination transistor Mge1 is controlled by the input signal D. A source terminal and a drain terminal of the first glitch elimination transistor Mge1 are connected together, and further coupled to the negative output terminal OutN without passing through the second cascode transistor Mc2. A gate terminal of the second glitch elimination transistor Mge2 is controlled by the inverted input signal Db. A source terminal and a drain terminal of the second glitch elimination transistor Mge2 are connected together, and further coupled to the positive output terminal OutP without passing through the first cascode transistor Mc1. Note that the source terminal and the drain terminal of the first glitch elimination Mge1 transistor are directly connected to the drain terminal of the second cascode transistor Mc2 rather than being directly connected to the source terminal of the second cascode transistor Mc2, and the source terminal and the drain terminal of the second glitch elimination transistor Mge2 are directly connected to the drain terminal of the first cascode transistor Mc1 rather than being directly connected to the source terminal of the first cascode transistor Mc1. At the differential analog output port (OutP and OutN), compared with the parasitic capacitors contributed by the multiple conversion cells, the parasitic capacitance due to the direct trace between a glitch elimination pair and the differential analog output port is relatively small. The efficiency of glitch elimination is good.

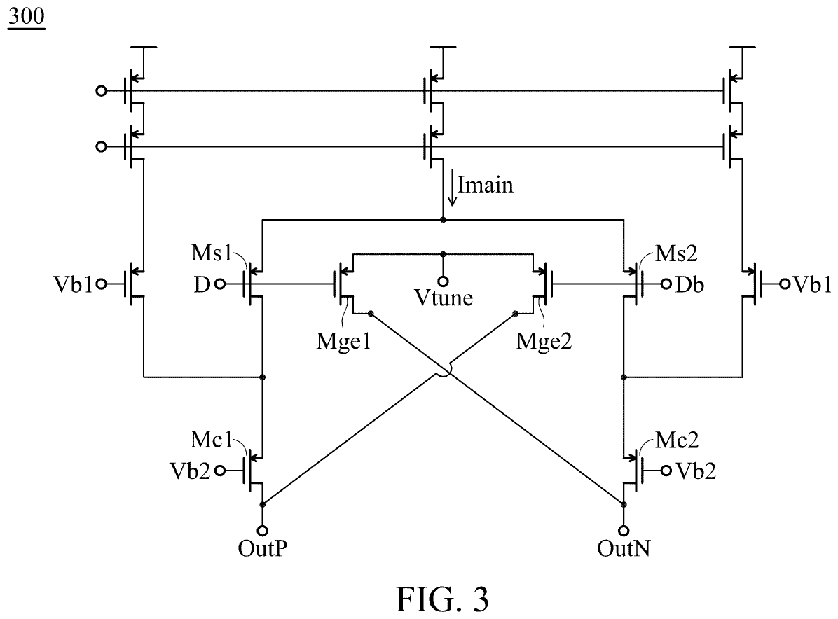

The glitch elimination pair (Mge1 and Mge2) may also help skew alignment between the different conversion cells. FIG. 3 depicts a conversion cell 300 capable of glitch elimination as well as skew alignment in accordance with an exemplary embodiment of the disclosure.

In FIG. 3, the drain terminal of the first glitch elimination transistor Mge1 is directly connected to the drain terminal of the second cascode transistor Mc2 rather than being directly connected to the source terminal of the second cascode transistor Mc2, and the drain terminal of the second glitch elimination transistor Mge2 is directly connected to the drain terminal of the first cascode transistor Mc1 rather than being directly connected to the source terminal of the first cascode transistor Mc1. Efficient glitch elimination is still achieved.

However, in comparison with the conversion cell 200 of FIG. 2, in the conversion cell 300 of FIG. 3, the source terminal and the drain terminal of the first glitch elimination transistor Mge1 are not connected together, and the source terminal and the drain terminal of the second glitch elimination transistor Mge2 are also not connected together. Instead, a source terminal of the first glitch elimination transistor Mge1 and a source terminal of the second glitch elimination transistor Mge2 are connected together for skew alignment. Specifically, the source terminal of the first glitch elimination transistor Mge1 and the source terminal of the second glitch elimination transistor Mge2 are controlled by a skew alignment voltage Vtune. By adjusting the skew alignment voltage Vtune of each conversion cell 104_#, the parasitic capacitance between the gate terminal and the source terminal of the glitch elimination transistor Mge1/Mge2 is changed, thereby modifying the transition speed of the input D/Db. In this manner, skew alignment between the different conversion cells 104_(k−1) . . . 104_0 is achieved. Note that the skew alignment voltage Vtune is tuned between a specific range to operate the first glitch elimination transistor Mge1 and the second glitch elimination transistor Mge2 within their cut-off regions, to perform glitch elimination and skew alignment at the differential analog output port (OutP and OutN) without degrading the DAC accuracy. In an exemplary embodiment, the different conversion cells are separately controlled by their skew alignment voltages (Vtune). In another exemplary embodiment, the different conversion cells share the same skew alignment voltage (Vtune).

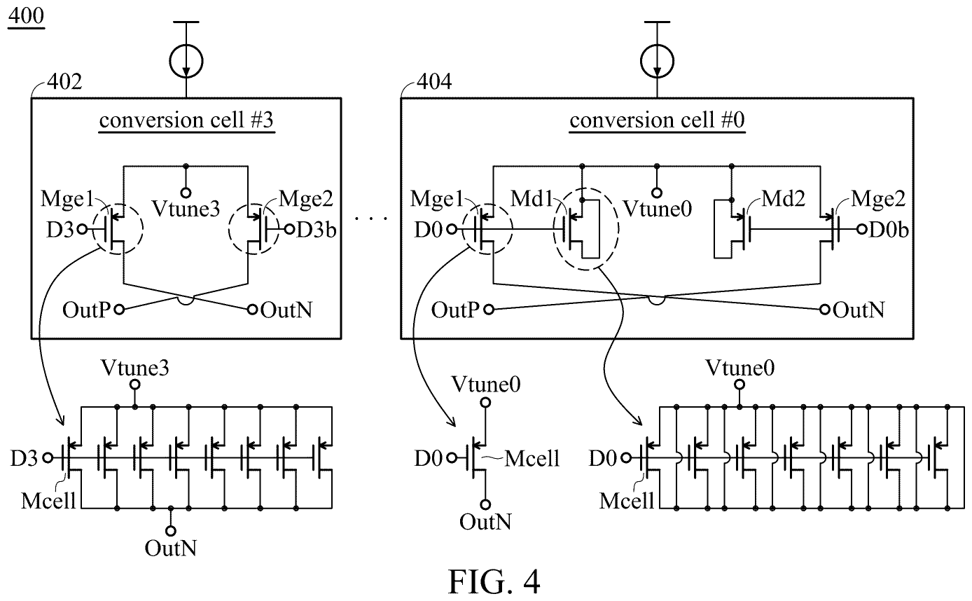

In some exemplary embodiments, the different conversion cells are of the same size, which result in dummy transistors. FIG. 4 illustrates a current-steering DAC 400 using dummy transistors in its glitch elimination design. Referring to the #3 conversion cell 402 corresponding to the input signal D3, the first glitch elimination transistor Mge1 and the second glitch elimination transistor Mge2 are each formed by 8 (N, an integer greater than 1) transistor cells Mcell which are connected in parallel. Referring to the #0 conversion cell 404 corresponding to the input signal D0, the first glitch elimination transistor Mge1 and the second glitch elimination transistor Mge2 are each formed by 1 (M, an integer smaller than N) transistor cell Mcell. To have the same size as the #3 conversion cell 402, the #0 conversion cell 404 further has a first dummy transistor Md1 and a second dummy transistor Md2, are each formed by 7 (which is N-M) transistor cells Mcell connected in parallel. Specifically, the first dummy transistor Md1 has a gate terminal controlled by an input signal D0 corresponding to the #0 conversion cell 404, and the second dummy transistor Md2 has a gate terminal controlled by the inverted input signal DOb corresponding to the #0 conversion cell 404. And, a source terminal and a drain terminal of each dummy transistor Md1/Md2 are connected together to be controlled by the skew alignment voltage Vtune0 corresponding to the #0 conversion cell 404. In this manner, the glitch elimination pair of the #0 conversion cell 404 including the dummy design has the same size of the glitch elimination pair of the #3 conversion cell 402.

In some exemplary embodiments, the number M is greater than 1. For any conversion cell having M (greater than 1 and lower than N) transistor cells to form a glitch elimination transistor Mge1/Mge2, the M transistor cells are connected in parallel, and the dummy design is also allowed.

Any current-steering DAC with the proposed glitch elimination pair (Mge1 and Mge2) coupled to the differential analog output port (OutN and OutP) without passing through the cascode pair (Mc2 and Mc1) should be considered within the scope of the disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic system including a current-steering digital-to-analog converter, wherein the current-steering digital-to-analog converter comprises a plurality of conversion cells, and each conversion cell comprises:
a differential switch pair, controlled by an input signal and an inverted input signal, to couple a current source to a positive output terminal and a negative output terminal of a differential analog output port;
a cascode pair, coupled between the differential switch pair and the differential analog output port; and
a glitch elimination pair, controlled by the input signal and the inverted input signal to eliminate glitches at the differential analog output port,
wherein the glitch elimination pair is coupled to the differential analog output port without passing through the cascode pair.

2. The electronic system as claimed in claim 1, wherein:
the glitch elimination pair comprises a first glitch elimination transistor and a second glitch elimination transistor;
a gate terminal of the first glitch elimination transistor is controlled by the input signal;
a source terminal and a drain terminal of the first glitch elimination transistor are connected together, and further coupled to the negative output terminal without passing through the cascode pair;
a gate terminal of the second glitch elimination transistor is controlled by the inverted input signal; and
a source terminal and a drain terminal of the second glitch elimination transistor are connected together, and further coupled to the positive output terminal without passing through the cascode pair.

3. The electronic system as claimed in claim 2, wherein:
the differential switch pair comprises a first switch transistor and a second switch transistor;
the cascode pair comprises a first cascode transistor and a second cascode transistor;
a gate terminal of the first switch transistor is controlled by the input signal to couple the current source to the positive output terminal through the first cascode transistor; and
a gate terminal of the second switch transistor is controlled by the inverted input signal to couple the current source to the negative output terminal through the second cascode transistor.

4. The electronic system as claimed in claim 3, wherein:
the source terminal and the drain terminal of the first glitch elimination transistor are directly connected to the negative output terminal without passing through the second cascode transistor; and
the source terminal and the drain terminal of the second glitch elimination transistor are directly connected to the positive output terminal without passing through the first cascode transistor.

5. The electronic system as claimed in claim 3, wherein:
a source terminal of the first switch transistor is coupled to the current source, a drain terminal of the first switch transistor is coupled to a source terminal of the first cascode transistor, and a drain terminal of the first cascode transistor is coupled to the positive output terminal; and
a source terminal of the second switch transistor is coupled to the current source, a drain terminal of the second switch transistor is coupled to a source terminal of the second cascode transistor, and a drain terminal of the second cascode transistor is coupled to the negative output terminal.

6. The electronic system as claimed in claim 5, wherein:
the source terminal and the drain terminal of the first glitch elimination transistor are directly connected to the drain terminal of the second cascode transistor rather than being directly connected to the source terminal of the second cascode transistor; and
the source terminal and the drain terminal of the second glitch elimination transistor are directly connected to the drain terminal of the first cascode transistor rather than being directly connected to the source terminal of the first cascode transistor.

7. The electronic system as claimed in claim 1, wherein:
the glitch elimination pair comprises a first glitch elimination transistor and a second glitch elimination transistor;
a gate terminal of the first glitch elimination transistor is controlled by the input signal;
a drain terminal of the first glitch elimination transistor is coupled to the negative output terminal without passing through the cascode pair;
a gate terminal of the second glitch elimination transistor is controlled by the inverted input signal;
a drain terminal of the second glitch elimination transistor is coupled to the positive output terminal without passing through the cascode pair; and
a source terminal of the first glitch elimination transistor and a source terminal of the second glitch elimination transistor are connected together.

8. The electronic system as claimed in claim 7, wherein:
the source terminal of the first glitch elimination transistor and the source terminal of the second glitch elimination transistor are controlled by a skew alignment voltage, for skew alignment between different conversion cells.

9. The electronic system as claimed in claim 7, wherein:
the source terminal of the first glitch elimination transistor and the source terminal of the second glitch elimination transistor are controlled by a skew alignment voltage; and
the different conversion cells share the same skew alignment voltage.

10. The electronic system as claimed in claim 8, wherein:
the differential switch pair comprises a first switch transistor and a second switch transistor;
the cascode pair comprises a first cascode transistor and a second cascode transistor;
a gate terminal of the first switch transistor is controlled by the input signal to couple the current source to the positive output terminal through the first cascode transistor; and
a gate terminal of the second switch transistor is controlled by the inverted input signal to couple the current source to the negative output terminal through the second cascode transistor.

11. The electronic system as claimed in claim 10, wherein:
the drain terminal of the first glitch elimination transistor is directly connected to the negative output terminal without passing through the second cascode transistor; and
the drain terminal of the second glitch elimination transistor is directly connected to the positive output terminal without passing through the first cascode transistor.

12. The electronic system as claimed in claim 10, wherein:
a source terminal of the first switch transistor is coupled to the current source, a drain terminal of the first switch transistor is coupled to a source terminal of the first cascode transistor, and a drain terminal of the first cascode transistor is coupled to the positive output terminal; and
a source terminal of the second switch transistor is coupled to the current source, a drain terminal of the second switch transistor is coupled to a source terminal of the second cascode transistor, and a drain terminal of the second cascode transistor is coupled to the negative output terminal.

13. The electronic system as claimed in claim 12, wherein:
the drain terminal of the first glitch elimination transistor is directly connected to the drain terminal of the second cascode transistor rather than being directly connected to the source terminal of the second cascode transistor; and
the drain terminal of the second glitch elimination transistor is directly connected to the drain terminal of the first cascode transistor rather than being directly connected to the source terminal of the first cascode transistor.

14. The electronic system as claimed in claim 8, wherein:
the skew alignment voltage operates the first glitch elimination transistor and the second glitch elimination transistor within a cut-off region.

15. The electronic system as claimed in claim 8, wherein:
a first glitch elimination transistor and a second glitch elimination transistor of a first conversion cell are each formed by N transistor cells connected in parallel, where N is an integer greater than 1;
a first glitch elimination transistor and a second glitch elimination transistor of a second conversion cell are each formed by M transistor cells connected in parallel, where M is an integer smaller than N.

16. The electronic system as claimed in claim 15, wherein the second conversion cell further comprises:
a first dummy transistor, formed by (N-M) transistor cells connected in parallel, having a gate terminal controlled by an input signal corresponding to the second conversion cell, wherein a source terminal and a drain terminal of the first dummy transistor are connected together to be controlled by a skew alignment voltage corresponding to the second conversion cell; and
a second dummy transistor, former by (N-M) transistor cells connected in parallel, having a gate terminal controlled by an inverted input signal corresponding to the second conversion cell, wherein a source terminal and a drain terminal of the second dummy transistor are connected together to be controlled by the skew alignment voltage corresponding to the second conversion cell.
